(19) United States
(12) Patent Application Publication
(10) Pub. No.: US 2010/0046560 A1
(43) Pub. Date: Feb. 25, 2010

(54) Dispersion managed fiber stretcher and compressor for high energy/power femtosecond fiber laser

(76) Inventor: Jian Liu, Sunnyvale, CA (US)

Correspondence Address: JOHN MARTIN TABOADA, 1923 N. NEW BRAUNFELS, SAN ANTONIO, TX, 78208, US

(21) Appl. No.: 12/542,904

(22) Filed: Aug. 18, 2009

Related U.S. Application Data
(60) Provisional application No. 61/189,685, filed on Aug. 21, 2008.

(51) Int. Cl. H01S 3/30; H01S 3/10; H01S 5/00

(52) U.S. Cl. 372/6; 372/9; 372/50.22

(57) ABSTRACT

Methods and systems for generating high energy, high power, ultra-short laser pulses are disclosed, including coupling an electromagnetic radiation pulse emitted from a seed to a photonic crystal fiber stretcher; coupling the electromagnetic radiation pulse exiting the photonic crystal fiber stretcher to a preamplifier; coupling the electromagnetic radiation pulse exiting the preamplifier to a pulse picker; coupling the electromagnetic radiation pulse exiting the pulse picker to a high power amplifier; coupling the electromagnetic radiation pulse exiting the high power amplifier to a photonic crystal fiber compressor; and coupling out the electromagnetic radiation pulse from the photonic crystal fiber compressor. Other embodiments are described and claimed.

### I. CROSS REFERENCE TO RELATED APPLICATIONS

The inventor claims priority to provisional patent application No. 61/189,685 filed on Aug. 21, 2008.

### II. BACKGROUND

The invention relates generally to the field of using photonic crystal fibers in dispersion managed high energy and high power femtosecond fiber lasers.

### III. SUMMARY

In one respect, disclosed is a fiber laser system comprising: a seed laser coupled to an input of a photonic crystal fiber stretcher, wherein an output of the photonic crystal fiber stretcher is coupled to an input of a preamplifier; a high power amplifier comprising an input and an output, wherein the input of the high power amplifier is coupled to an output of the preamplifier; and a photonic crystal fiber compressor coupled to the output of the high power amplifier.

In another respect, disclosed is a fiber laser system comprising: a seed laser coupled to an input of a photonic crystal fiber stretcher, wherein an output of the photonic crystal fiber stretcher is coupled to an input of a preamplifier; a pulse picker comprising an input and an output, wherein the input of the pulse picker is coupled to an output of the preamplifier; a high power amplifier comprising an input and an output, wherein the input of the high power amplifier is coupled to the output of the pulse picker; and a photonic crystal fiber compressor coupled to the output of the high power amplifier.

In another respect, disclosed is a method for generating high energy, high power, ultra-short laser pulses, the method comprising: coupling an electromagnetic radiation pulse emitted from a seed to a photonic crystal fiber stretcher; coupling the electromagnetic radiation pulse exiting the photonic crystal fiber stretcher to a preamplifier; coupling the electromagnetic radiation pulse exiting the preamplifier to a high power amplifier; coupling the electromagnetic radiation pulse exiting the high power amplifier to a photonic crystal fiber compressor; and coupling out the electromagnetic radiation pulse from the photonic crystal fiber compressor.

In yet another respect, disclosed is a method for generating high energy, high power, ultra-short laser pulses, the method comprising: coupling an electromagnetic radiation pulse emitted from a seed to a photonic crystal fiber stretcher; coupling the electromagnetic radiation pulse exiting the photonic crystal fiber stretcher to a preamplifier; coupling the electromagnetic radiation pulse exiting the preamplifier to a pulse picker; coupling the electromagnetic radiation pulse exiting the pulse picker to a high power amplifier; coupling the electromagnetic radiation pulse exiting the high power amplifier to a photonic crystal fiber compressor; and coupling out the electromagnetic radiation pulse from the photonic crystal fiber compressor.

Numerous additional embodiments are also possible.

### IV. BRIEF DESCRIPTION OF THE DRAWINGS

Other objects and advantages of the invention may become apparent upon reading the detailed description and upon reference to the accompanying drawings.

FIG. 1 is a schematic block diagram showing the system layout of a high energy and high power fiber laser system, in accordance with some embodiments.

FIGS. 2(a), (b), (c), and (d) show schematics of cross sections for different photonic crystal fibers which exhibit normal dispersion, in accordance with some embodiments.

FIGS. 3(a), (b), and (c) are graphs of the dispersion profiles for photonic crystal fibers for the structures shown in FIGS. 2(a), (b), and (d), in accordance with some embodiments.

FIG. 4 is a graph showing the effect on dispersion as a function of wavelength for various air-fill factors, in accordance with some embodiments.

FIGS. 5(a), (b), and (c) show schematics of cross sections for different photonic crystal fibers which exhibit anomalous dispersion, in accordance with some embodiments.

FIG. 6 is a graph of the dispersion profile for hollow-core photonic bandgap fibers, in accordance with some embodiments.

FIGS. 7(a) and (b) are graphs of dispersion profiles and average dispersion of partially, relative dispersion slope matched photonic crystal fibers, in accordance with some embodiments.

FIG. 8 is a flow diagram illustrating a method to generate ultra-short high energy and high power laser pulses, in accordance with some embodiments.

While the invention is subject to various modifications and alternative forms, specific embodiments thereof are shown by way of example in the drawings and the accompanying detailed description. It should be understood, however, that the drawings and detailed description are not intended to limit the invention to the particular embodiments. This disclosure is instead intended to cover all modifications, equivalents, and alternatives falling within the scope of the present invention as defined by the appended claims.

### V. DETAILED DESCRIPTION

One or more embodiments of the invention are described below. It should be noted that these and any other embodiments are exemplary and are intended to be illustrative of the invention rather than limiting. While the invention is widely applicable to different types of systems, it is impossible to include all of the possible embodiments and contexts of the invention in this disclosure. Upon reading this disclosure, many alternative embodiments of the present invention will be apparent to persons of ordinary skill in the art.

High energy and high power femtosecond (fs) fiber lasers face several technical challenges in terms of fiber design, high power amplification, nonlinear effects, and stretching/compression. In such lasers, higher order dispersions such as third order dispersion will significantly impact the pulse quality due to the higher stretching ratios involved in the chirped pulse amplification. Additionally, efficiently compressing the pulse below 200 fs after amplification presents a challenge. The disclosed invention overcomes these challenges by using a photonic crystal fiber (PCF) stretcher matched in dispersion and dispersion slope with a photonic crystal fiber compressor. The photonic crystal fiber compressor may be a hollow-core photonic bandgap fiber (PBF) or other PCF which exhibits anomalous, or positive, dispersion.

There are essentially two different kinds of photonic crystal fibers: solid-core and hollow-core microstructered fibers (MOFs). Solid-core MOFs have central core regions made from silica or some other solid phase waveguiding material and work on the principle of step-index total internal reflection. Hollow-core MOFs on the other hand have a hollow central core region whose volume is filled with air or some other gas phase material. Unlike solid-core MOFs, the guiding mechanism for hollow-core MOFs is based on a photonic bandgap that arises from a regular two-dimensional array of air holes in the cladding. The main parameter of a fiber is its effective index of refraction whose real component contains the dispersion information as expressed in equation 1,

$$D = - \frac{λ}{c} \frac{{\partial }^{2} Re ( {n}_{eff} )}{\partial {λ}^{2}} \qquad ( 1 )$$

and whose imaginary component allows the calculation of the losses as expressed in equation 2,

$$L = \frac{40 π}{ln ( 10 ) λ} Im ( {n}_{eff} ) . \qquad ( 2 )$$

The effective index is composed of the material component and the geometric component as expressed in equation 3,

n_{eff}=n_{eff}^{mat}+n_{eff}^{geom}. (3)

Therefore, in order to influence the dispersion for a given material, only the geometric component can be manipulated. For both hexagonal and square PCF fibers, the geometry can be described by the diameter of the air holes (d), the distance between the centers of two adjacent holes (Λ), or pitch, and the number rings (Nᵣ) The ratio between the diameter of the air holes and the distance between centers of two adjacent holes is defined as the air-fill factor (d/Λ). For a solid-core MOF, changing any of these parameters, the ring number, the air hole diameter, or the pitch, and hence, the air-fill factor, will change the dispersion and dispersion slope of the solid-core PCF. On the other hand, for a hollow-core MOF, the group velocity dispersion (GVD) mainly arises from the photonic bandgap itself instead of the properties of the material. Hollow-core MOFs also have negligible nonlinearities that are 1000 times smaller than that of conventional single mode fibers. An anomalous-GVD segment with negligible nonlinearity is a prerequisite to wave-breaking-free or self-similar operation of femtosecond fiber lasers.

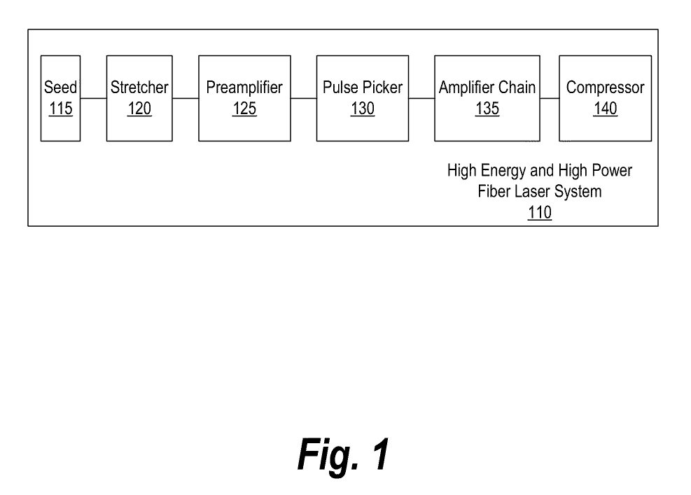

FIG. 1 is a schematic block diagram showing the system layout of a high energy and high power fiber laser system, in accordance with some embodiments.

In some embodiments, the fiber laser system is comprised of a seed, a stretcher, a preamplifier, a pulse picker, an amplifier chain, and a compressor, as shown in block 110. A laser pulse from the seed laser 115 is coupled into a stretcher 120. The stretcher 120 stretches the laser pulse before being coupled into the preamplifier 125. Next, depending on the desired repetition rate, an optional pulse picker 130 is coupled to the output of the preamplifier 125 and to the input of the amplifier chain 135. Finally, the compressor 140 takes the pulses from the amplifier chain 135 and reduces the pulse width to produce ultra-short laser pulses with high energy and high power.

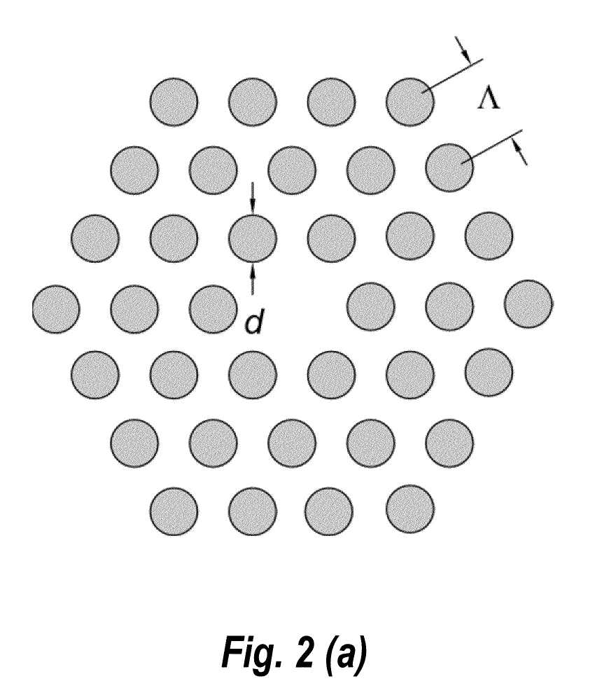

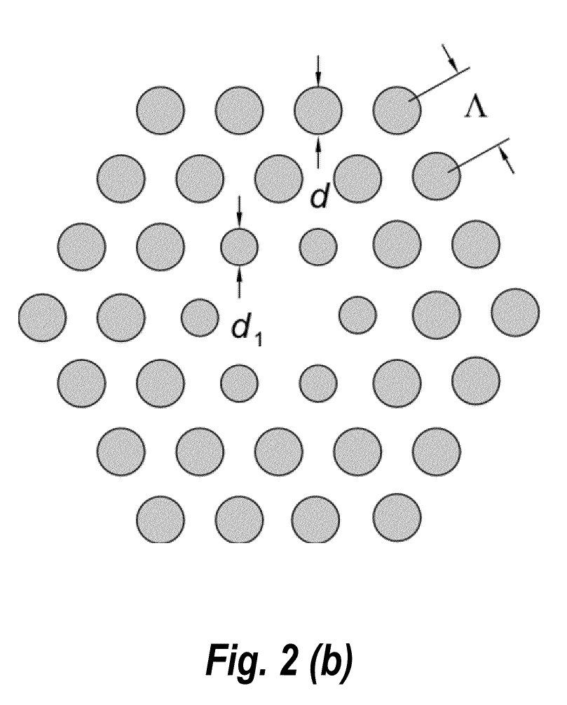

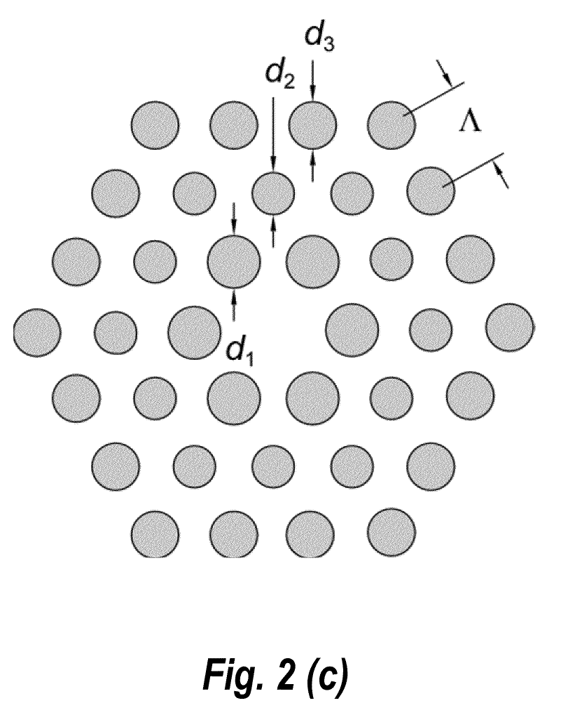

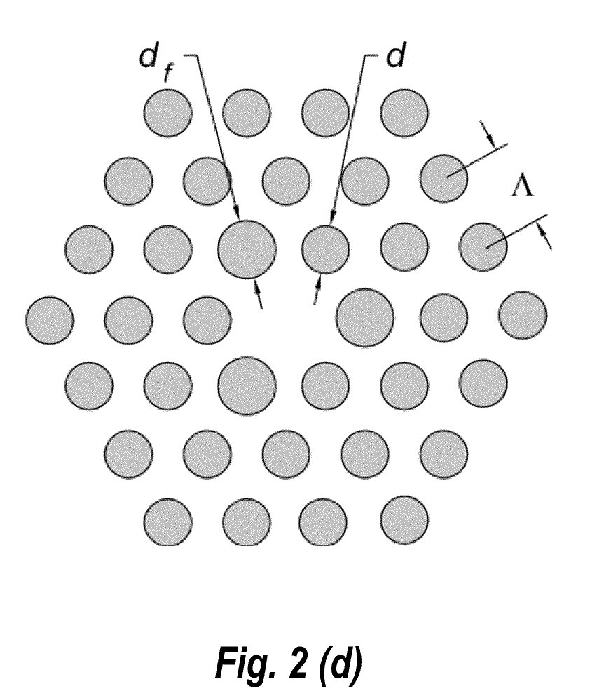

FIGS. 2(a), (b), (c), and (d) show schematics of cross sections for different photonic crystal fibers which exhibit normal dispersion, in accordance with some embodiments.

In some embodiments, the photonic crystal fiber may have a variety of cross sectional geometries. In FIG. 2(a), a cross section of a three ring solid-core hexagonal PCF is shown with an air hole diameter of d and a pitch of Λ. FIG. 2(b) shows a cross section of a three ring solid-core hexagonal PCF with an air hole diameter of d₁ and a pitch of Λ. The diameter of the air holes in the subsequent rings is d. FIG. 2(c) shows a cross section of a three ring solid-core hexagonal PCF with different air hole diameters for each of the three rings, d₁, d₂, and d₃, respectively. The PCF also has a pitch of Λ. FIG. 2(d) depicts a three ring solid-core hexagonal PCF with an overall air hole diameter of d and a pitch of Λ. FIG. 2(d) differs from FIG. 2(a) in that three of the air holes from the first ring have a different diameter, d_{f}. The diameter of the air holes from the first ring alternate from diameter d to diameter d_{f}. The PCF of FIG. 2(d) is said to have a triangular core resulting from the alternating sequence of air hole diameters for the first ring. All the PCFs shown in FIGS. 2(a), (b), (c), and (d) exhibit normal dispersions and negative dispersion slopes as a function of increasing wavelength. Such structures may be used as pulse stretchers in high energy and high power femtosecond fiber laser systems.

Various other structural combinations of FIGS. 2(a), (b), (c), and (d) are possible.

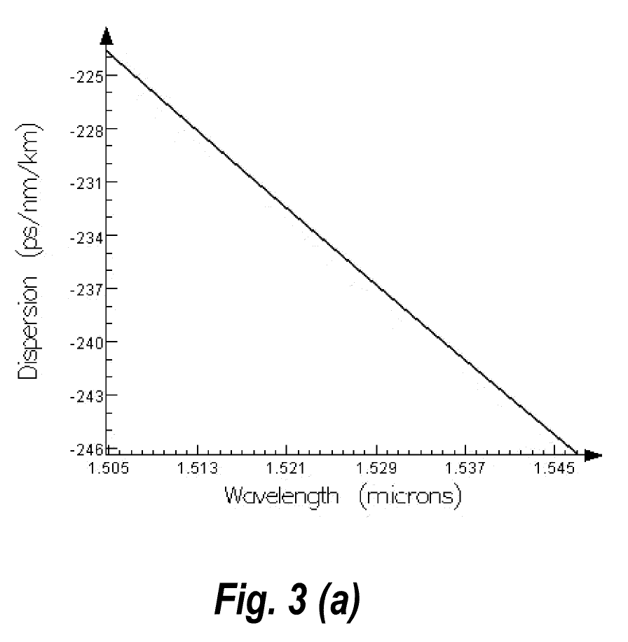

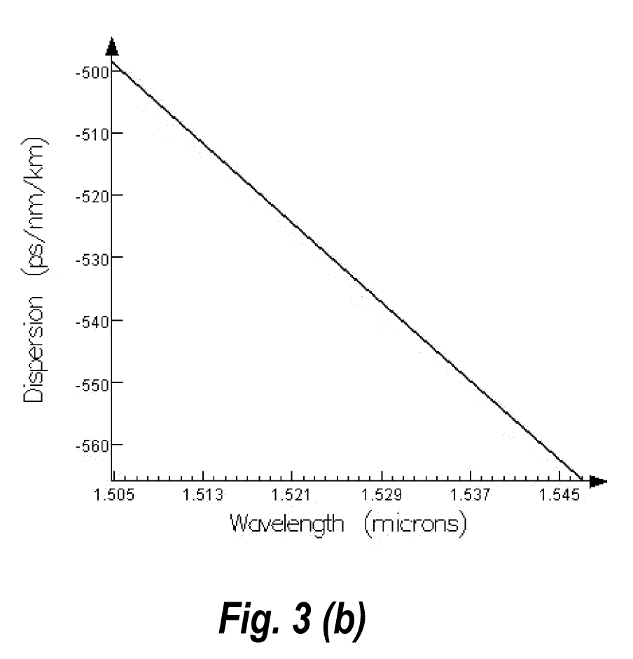

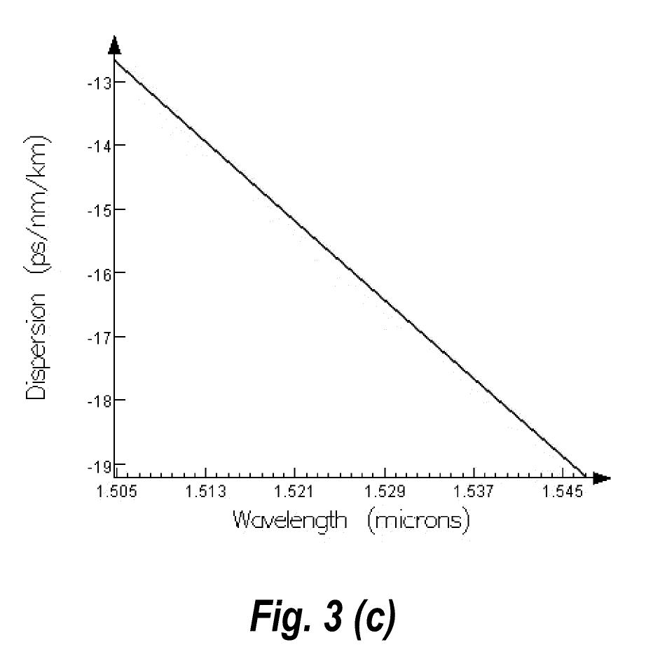

FIGS. 3(a), (b), and (c) are graphs of the dispersion profiles for photonic crystal fibers for the structures shown in FIGS. 2(a), (b), and (d), in accordance with some embodiments.

In some embodiments, the stretcher is comprised of a hexagonal solid-core photonic crystal fiber. FIG. 3(a) shows the dispersion profile across a 50 nm bandwidth for the PCF having an air hole diameter for the first ring that is smaller than the diameter of the air holes of the other rings. Schematically the PCF is shown in FIG. 2(b), where d₁ is less than d. The PCF also has an air-fill factor of 0.73 and as shown in FIG. 3(a), the average dispersion is roughly −236 ps/nm/km across the 50 nm bandwidth. FIG. 3(b) shows the dispersion profile across a 50 nm bandwidth for a PCF where all the air holes of the rings are the same and the air-fill factor is 0.9. Schematically the PCF is shown in FIG. 2(a). The PCF exhibits an average dispersion of approximately −535 ps/nm/km across the same 50 nm bandwidth as shown in FIG. 3(b). For the PCF having smaller diameter air holes for the first ring, FIG. 2(b), the pulse is confined more in the core and has an increased dispersion and dispersion slope than the PCF having the same diameter air holes for all the rings, FIG. 2(a).

In some embodiments, the stretcher is comprised of a hexagonal solid-core photonic crystal fiber. FIG. 3(c) shows the dispersion profile across a 50 nm bandwidth for the PCF shown in FIG. 2(d) having a diameter d of 0.65 μm, a diameter d_{f} of 0.82 μm, and a pitch of 1.6 μm. Such a structure has a normal dispersion and negative dispersion slope across the 1550 nm bandwidth.

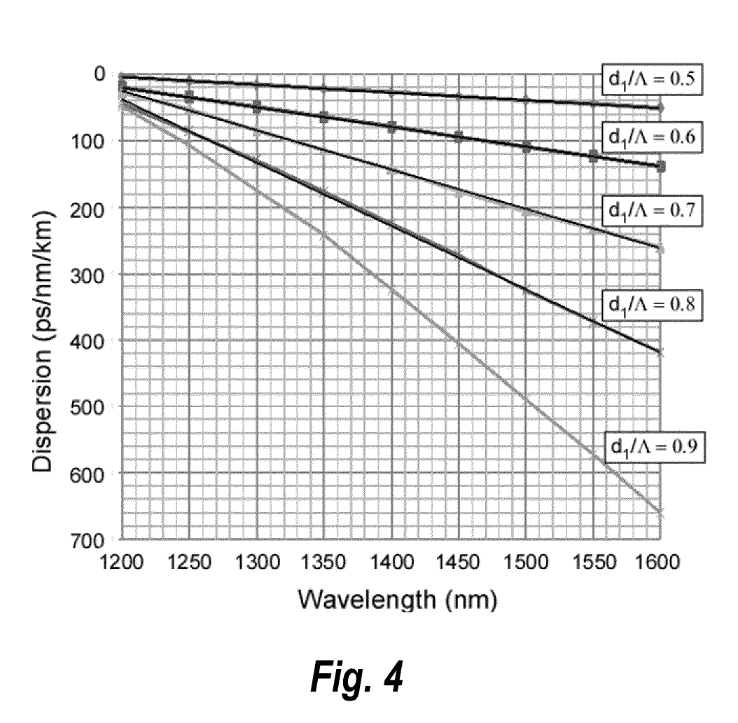

FIG. 4 is a graph showing the effect on dispersion as a function of wavelength for various air-fill factors, in accordance with some embodiments.

In some embodiments, by properly tailoring the air hole diameter and the pitch, it is possible to obtain the desired dispersion properties from PCFs with high air-filling fraction by compensating both the anomalous dispersion and the positive dispersion slope over the wavelength range around 1550 nm. The dispersion profile across the 1550 nm bandwidth can also be flattened by varying the air-hole diameters of the air-holes surrounding the core. FIG. 4 shows how dispersion as a function of wavelength varies for different air-fill factors for hexagonal solid-core PCFs having altered first ring air-hole diameters, d₁. Reducing the air-fill factor increases the dispersion parameter as well as the dispersion slope for all the wavelengths between 1200 nm and 1600 nm. Besides just changing the air-hole diameters of the first ring, it is possible to vary the air-hole diameters of the other surrounding rings. For example, decreasing the air-hole diameter of the second ring holes results in the dispersion parameter becoming more negative ˜−1500 ps/nm/km.

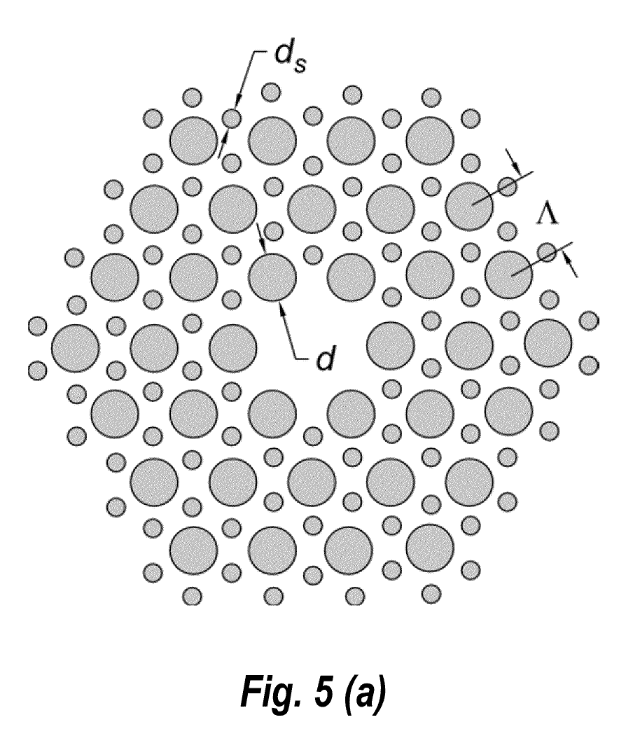

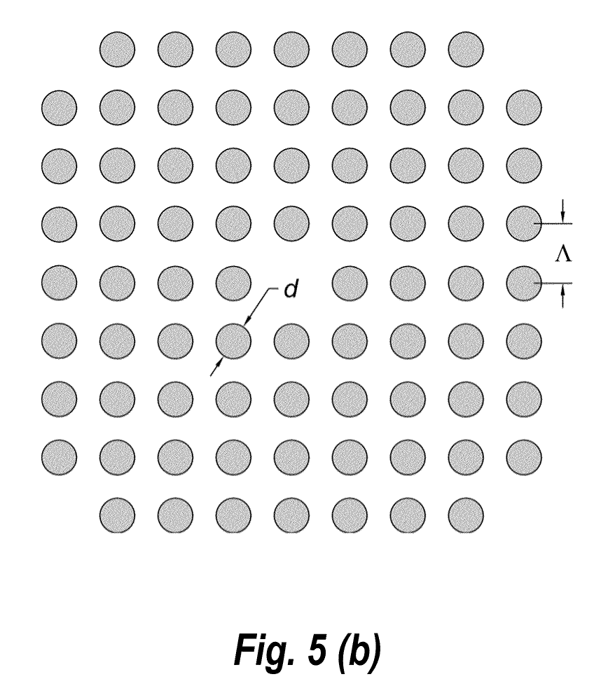

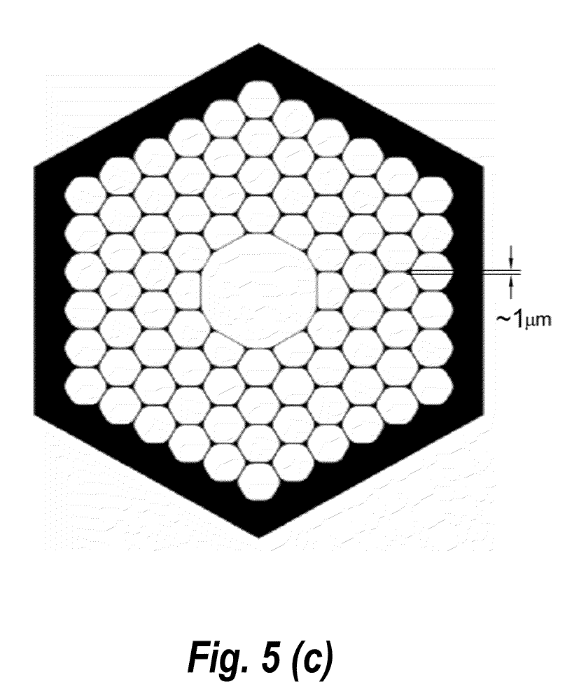

FIGS. 5(a), (b), and (c) show schematics of cross sections for different photonic crystal fibers which exhibit anomalous dispersion, in accordance with some embodiments.

In some embodiments, the photonic crystal fiber may be designed with anomalous dispersion. In FIG. 5(a), a cross section of a solid-core, large mode area fiber with seven central air holes removed is shown with an air hole diameter of d and a pitch of Λ. Surrounding each air hole of diameter d is another sub-ring of air holes with diameter d_{S}. Such a structure exhibits anomalous dispersion above 1.5 μm and across the 50 nm bandwidth, but depending on the air-fill factor, the dispersion slope may either be positive or negative beyond 1.55 μm. For an air-fill factor of 0.5 and a pitch of 2 μm, the PCF has a positive dispersion slope to about 1.55 μm, but above that wavelength, the dispersion slope becomes negative. For an air-fill factor of 0.9 and a pitch of 1.5 μm, the dispersion slope remains positive past 1.55 μm.

In some embodiments, the air holes of a solid-core PCF may be arranged in a square pattern. FIG. 5(b) shows a cross section of a square PCF with an air hole diameter of d and a pitch of Λ. Such structures, with pitches of 3 μm and air-fill factors of 0.5 and 0.9, exhibit anomalous dispersions with a positive dispersion slopes above 1.5 μm and across the 50 nm bandwidth. Unlike the structure in FIG. 5(a), the dispersion slope remains positive above 1.55 μm for both air-fill factors of 0.5 and 0.9.

In some embodiments, PCFs which have hollow-cores are known as photonic bandgap fibers. PBFs exhibit anomalous dispersions and positive dispersion slopes above 1.5 μm and across the 50 nm bandwidth. FIG. 5(c) shows a schematic of a hollow-core PBF. The hexagonal air holes are separated by a silica matrix with about one micron wall thickness. The hollow-core photonic bandgap fiber may also be filled with a gas phase material to change its dispersion and dispersion slope characteristics.

Various other structural combinations of FIGS. 5(a), (b), and (c) are possible.

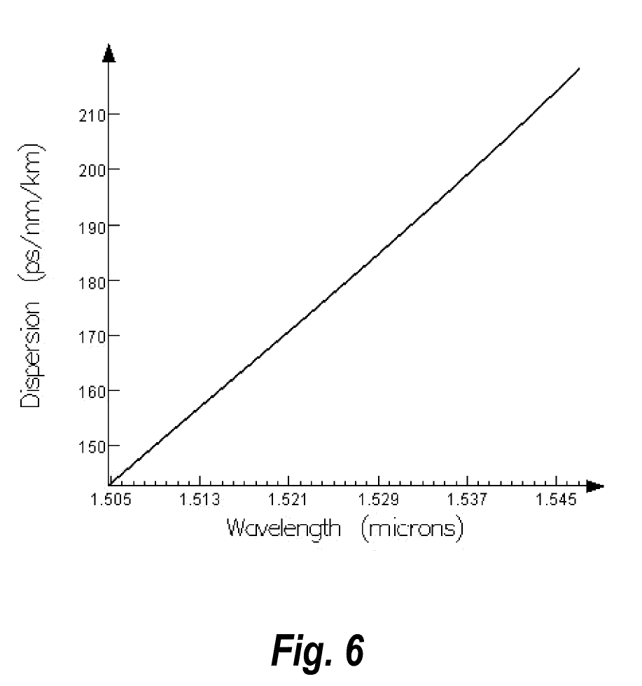

FIG. 6 is a graph of the dispersion profile for hollow-core photonic bandgap fibers, in accordance with some embodiments.

In some embodiments, a hollow-core photonic bandgap fiber with a silica matrix of air holes separated by inner walls with about one micron thickness exhibits anomalous dispersion and a positive dispersion slope above 1.5 μm and across the 50 nm bandwidth. The dispersion profile for a structure similar to that in FIG. 5(c) is shown in FIG. 6. The other structures shown in FIGS. 5(a) and (b) also exhibit anomalous dispersion and a positive dispersion slope across the 1550 nm bandwidth. Such structures may be used as pulse compressors in high energy and high power femtosecond fiber laser systems.

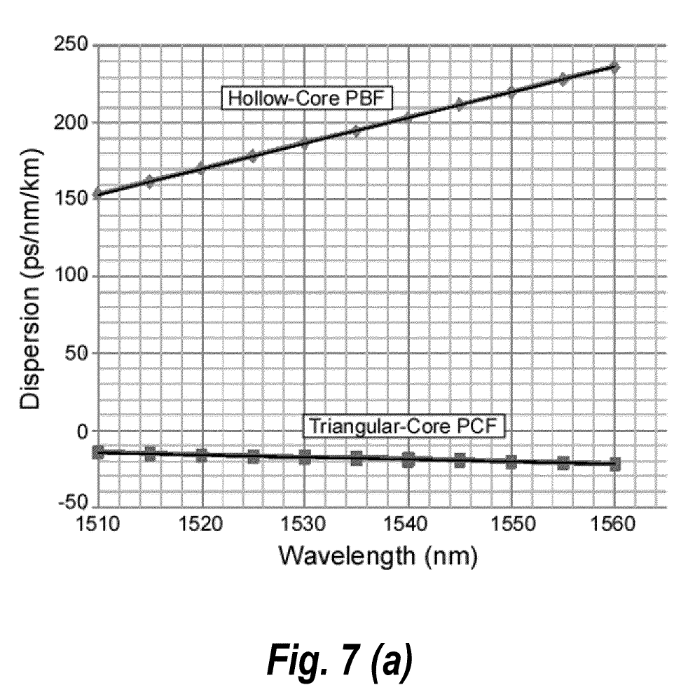

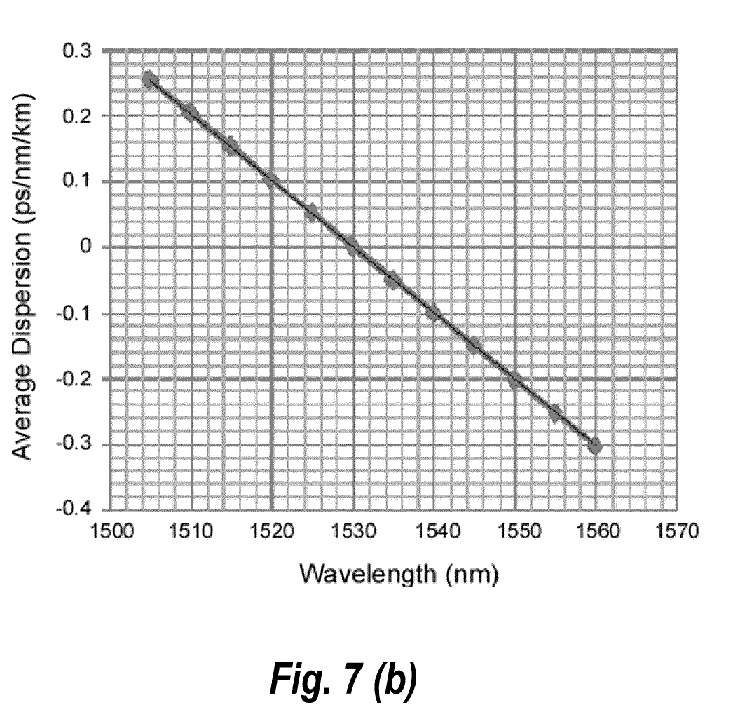

FIGS. 7(a) and (b) are graphs of dispersion profiles and average dispersion of partially, relative dispersion slope matched photonic crystal fibers, in accordance with some embodiments.

In some embodiments, the normal dispersion and negative dispersion slope of the fiber pulse stretcher is compensated by a fiber pulse compressor with anomalous dispersion and positive dispersion slope. If the ratio of dispersion to dispersion slope is the same for both fibers and the lengths of the fibers are adjusted so that the residual dispersion is exactly zero, then the residual dispersion slope will also necessarily be zero. The ratio of dispersion to dispersion slope is referred to as kappa and the inverse of kappa is defined as the relative dispersion slope. Complete dispersion compensation is achieved when the kappa values of the fiber stretcher and compressor are equal across the desired wavelength band.

In some embodiments, the triangular core PCF illustrated schematically in FIG. 2(d) and whose dispersion slope is graphed in FIG. 3(c) exhibits a relative dispersion slope of 0.00891 at 1530 nm. Such a fiber can be used as a pulse stretcher in a high energy and high power femtosecond fiber laser system and can be matched by an appropriate PCF compressor. One such PCF, is the hollow-core PBF illustrated schematically in FIG. 5(c) and whose dispersion slope is graphed in FIG. 6. This PBF exhibits a dispersion slope of 1.66 ps/nm²/km across the 1550 nm bandwidth and has a relative dispersion slope of 0.00864 at 1530 nm, thus substantially matching the relative dispersion slope at 1530 nm by more than 95%. The dispersion profiles of the PCF from FIG. 2(d) and the PBF from FIG. 5(c) are graphed together in FIG. 7(a) and their average dispersion over the 50 nm bandwidth is graphed in FIG. 7(b).

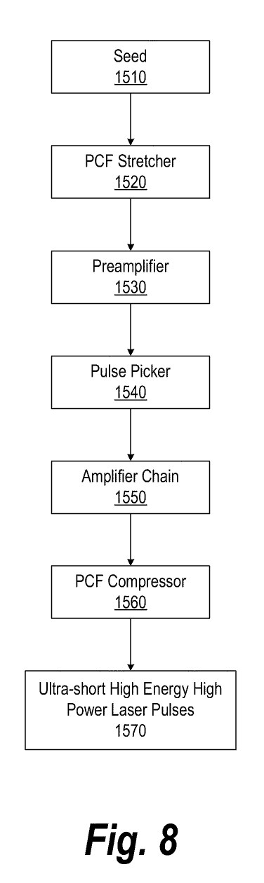

FIG. 8 is a flow diagram illustrating a method to generate ultra-short high energy and high power laser pulses, in accordance with some embodiments. In some embodiments, the method illustrated in FIG. 8 may be performed by one or more of the devices illustrated in FIG. 1, FIGS. 2, and FIGS. 5.

In order to generate ultra-short high energy and high power laser pulses from a fiber laser system, processing begins with the electromagnetic radiation pulse output from the seed laser 1510 first being coupled into a PCF stretcher 1520. The PCF stretcher 1520 exhibits normal dispersion and negative dispersion slope across the across the desired bandwidth. After the pulses have been stretched, they are coupled into a preamplifier 1530. Next, depending on the desired repetition rate, an optional pulse picker 1540 is coupled to the output of the preamplifier 1530. The pulses from the pulse picker 1540, or from the preamplifier 1530 if a pulse picker 1540 is not used, are then coupled into an amplifier chain 1550 to amplify the laser pulses. After the pulses have been amplified, they are subsequently compressed in a PCF compressor 1560 designed to substantially match the relative dispersion slope of the PCF stretcher 1520 to yield ultra-short high energy and high power laser pulses 1570.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

The benefits and advantages that may be provided by the present invention have been described above with regard to specific embodiments. These benefits and advantages, and any elements or limitations that may cause them to occur or to become more pronounced are not to be construed as critical, required, or essential features of any or all of the claims. As used herein, the terms “comprises,” “comprising,” or any other variations thereof, are intended to be interpreted as non-exclusively including the elements or limitations which follow those terms. Accordingly, a system, method, or other embodiment that comprises a set of elements is not limited to only those elements, and may include other elements not expressly listed or inherent to the claimed embodiment.

While the present invention has been described with reference to particular embodiments, it should be understood that the embodiments are illustrative and that the scope of the invention is not limited to these embodiments. Many variations, modifications, additions and improvements to the embodiments described above are possible. It is contemplated that these variations, modifications, additions and improvements fall within the scope of the invention as detailed within the following claims.

1. A fiber laser system comprising:
a seed laser coupled to an input of a photonic crystal fiber stretcher, wherein an output of the photonic crystal fiber stretcher is coupled to an input of a preamplifier;
a high power amplifier comprising an input and an output, wherein the input of the high power amplifier is coupled to an output of the preamplifier; and
a photonic crystal fiber compressor coupled to the output of the high power amplifier.

2. The fiber laser system of claim 1, wherein the high power amplifier comprises a series of one or more high power amplifiers.

3. The fiber laser system of claim 1, wherein the photonic crystal fiber stretcher comprises a solid core surrounded by one or more rings of air-holes.

4. The fiber laser system of claim 3, wherein the diameter of the air-holes of the innermost ring is smaller than the diameter of the air-holes of the other rings.

5. The fiber laser system of claim 3, wherein the air-holes of the innermost ring comprises a first set of air-holes having a first diameter and a second set of air-holes having a second diameter, wherein the first set of air-holes and the second set of air-holes are interlaced.

6. The fiber laser system of claim 1, wherein the photonic crystal fiber compressor comprises a hollow-core photonic bandgap fiber.

7. The fiber laser system of claim 6, wherein the hollow-core photonic bandgap fiber further comprises the hollow-core surrounded by an innermost ring of air-holes, wherein the innermost ring of air-holes is surrounded by a second ring of air-holes, wherein the diameter of the innermost ring of air-holes is larger than the diameter of the second ring of air-holes.

8. The fiber laser system of claim 6, wherein the hollow-core photonic bandgap fiber is filled with a gas phase material.

9. The fiber laser system of claim 1, wherein the photonic crystal fiber stretcher is configured to have normal dispersion and a negative dispersion slope; and the photonic crystal fiber compressor is configured to have anomalous dispersion and a positive dispersion slope.

10. The fiber laser system of claim 9, wherein the photonic crystal fiber stretcher and photonic crystal fiber compressor have matched relative dispersion slopes.

11. A fiber laser system comprising:
a seed laser coupled to an input of a photonic crystal fiber stretcher, wherein an output of the photonic crystal fiber stretcher is coupled to an input of a preamplifier;
a pulse picker comprising an input and an output, wherein the input of the pulse picker is coupled to an output of the preamplifier;
a high power amplifier comprising an input and an output, wherein the input of the high power amplifier is coupled to the output of the pulse picker; and
a photonic crystal fiber compressor coupled to the output of the high power amplifier.

12. The fiber laser system of claim 11, wherein the high power amplifier comprises a series of one or more high power amplifiers.

13. The fiber laser system of claim 11, wherein the photonic crystal fiber stretcher comprises a solid core surrounded by one or more rings of air-holes.

14. The fiber laser system of claim 13, wherein the diameter of the air-holes of the innermost ring is smaller than the diameter of the air-holes of the other rings.

15. The fiber laser system of claim 13, wherein the air-holes of the innermost ring comprises a first set of air-holes having a first diameter and a second set of air-holes having a second diameter, wherein the first set of air-holes and the second set of air-holes are interlaced.

16. The fiber laser system of claim 11, wherein the photonic crystal fiber compressor comprises a hollow-core photonic bandgap fiber.

17. The fiber laser system of claim 16, wherein the hollow-core photonic bandgap fiber further comprises the hollow-core surrounded by an innermost ring of air-holes, wherein the innermost ring of air-holes is surrounded by a second ring of air-holes, wherein the diameter of the innermost ring of air-holes is larger than the diameter of the second ring of air-holes.

18. The fiber laser system of claim 16, wherein the hollow-core photonic bandgap fiber is filled with a gas phase material.

19. The fiber laser system of claim 11, wherein the photonic crystal fiber stretcher is configured to have normal dispersion and a negative dispersion slope; and the photonic crystal fiber compressor is configured to have anomalous dispersion and a positive dispersion slope.

20. The fiber laser system of claim 19, wherein the photonic crystal fiber stretcher and photonic crystal fiber compressor have matched relative dispersion slopes.

21. A method for generating high energy, high power, ultra-short laser pulses, the method comprising:
coupling an electromagnetic radiation pulse emitted from a seed to a photonic crystal fiber stretcher;
coupling the electromagnetic radiation pulse exiting the photonic crystal fiber stretcher to a preamplifier;
coupling the electromagnetic radiation pulse exiting the preamplifier to a high power amplifier;
coupling the electromagnetic radiation pulse exiting the high power amplifier to a photonic crystal fiber compressor; and
coupling out the electromagnetic radiation pulse from the photonic crystal fiber compressor.

22. The method of claim 21, wherein the high power amplifier comprises a series of one or more high power amplifiers.

23. The method of claim 21, wherein the photonic crystal fiber stretcher comprises a solid core surrounded by one or more rings of air-holes.

24. The method of claim 23, wherein the diameter of the air-holes of the innermost ring is smaller than the diameter of the air-holes of the other rings.

25. The method of claim 23, wherein the air-holes of the innermost ring comprises a first set of air-holes having a first diameter and a second set of air-holes having a second diameter, wherein the first set of air-holes and the second set of air-holes are interlaced.

26. The method of claim 21, wherein the photonic crystal fiber compressor comprises a hollow-core photonic bandgap fiber.

27. The method of claim 26, wherein the hollow-core photonic bandgap fiber further comprises the hollow-core surrounded by an innermost ring of air-holes, wherein the innermost ring of air-holes is surrounded by a second ring of air-holes, wherein the diameter of the innermost ring of air-holes is larger than the diameter of the second ring of air-holes.

28. The method of claim 26, wherein the hollow-core photonic bandgap fiber is filled with a gas phase material.

29. The method of claim 21, wherein the photonic crystal fiber stretcher is configured to have normal dispersion and a negative dispersion slope; and the photonic crystal fiber compressor is configured to have anomalous dispersion and a positive dispersion slope.

30. The method of claim 29, wherein the photonic crystal fiber stretcher and photonic crystal fiber compressor have matched relative dispersion slopes.

31. A method for generating high energy, high power, ultra-short laser pulses, the method comprising:
coupling an electromagnetic radiation pulse emitted from a seed to a photonic crystal fiber stretcher;
coupling the electromagnetic radiation pulse exiting the photonic crystal fiber stretcher to a preamplifier;
coupling the electromagnetic radiation pulse exiting the preamplifier to a pulse picker;
coupling the electromagnetic radiation pulse exiting the pulse picker to a high power amplifier;
coupling the electromagnetic radiation pulse exiting the high power amplifier to a photonic crystal fiber compressor; and
coupling out the electromagnetic radiation pulse from the photonic crystal fiber compressor.

32. The method of claim 31, wherein the high power amplifier comprises a series of one or more high power amplifiers.

33. The method of claim 31, wherein the photonic crystal fiber stretcher comprises a solid core surrounded by one or more rings of air-holes.

34. The method of claim 33, wherein the diameter of the air-holes of the innermost ring is smaller than the diameter of the air-holes of the other rings.

35. The method of claim 33, wherein the air-holes of the innermost ring comprises a first set of air-holes having a first diameter and a second set of air-holes having a second diameter, wherein the first set of air-holes and the second set of air-holes are interlaced.

36. The method of claim 31, wherein the photonic crystal fiber compressor comprises a hollow-core photonic bandgap fiber.

37. The method of claim 36, wherein the hollow-core photonic bandgap fiber further comprises the hollow-core surrounded by an innermost ring of air-holes, wherein the innermost ring of air-holes is surrounded by a second ring of air-holes, wherein the diameter of the innermost ring of air-holes is larger than the diameter of the second ring of air-holes.

38. The method of claim 36, wherein the hollow-core photonic bandgap fiber is filled with a gas phase material.

39. The method of claim 31, wherein the photonic crystal fiber stretcher is configured to have normal dispersion and a negative dispersion slope; and the photonic crystal fiber compressor is configured to have anomalous dispersion and a positive dispersion slope.

40. The method of claim 39, wherein the photonic crystal fiber stretcher and photonic crystal fiber compressor have matched relative dispersion slopes.
